(19) United States
(12) Patent Application Publication
(10) Pub. No.: US 2015/0349159 A1
(43) Pub. Date: Dec. 3, 2015

(54) BENDABLE SOLAR CELL CAPABLE OF OPTIMIZING THICKNESS AND CONVERSION EFFICIENCY

(71) Applicant: National Tsing Hua University, Hsinchu (TW)

(72) Inventor: Jer-Liang YEH, Taichung City (TW)

(73) Assignee: National Tsing Hua University, Hsinchu (TW)

(21) Appl. No.: 14/288,757

(22) Filed: May 28, 2014

(51) Int. Cl. H01L 31/0392

(52) U.S. Cl. CPC H01L 31/03926

(57) ABSTRACT

A bendable solar cell capable of optimizing thickness and conversion efficiency, comprising: a solar cell body having a top surface, a bottom surface, and four side walls; and a layer of nanostructures located on said side walls, wherein said solar cell body has a thickness ranging from about 50 μm to about 120 μm, and said layer of nanostructures has a depth ranging from about 2 μm to 8 μm.

### BACKGROUND OF THE INVENTION

1. Field of the Invention

The present invention relates to a solar cell, especially to a bendable solar cell capable of optimizing thickness and energy-conversion efficiency thereof.

2. Description of the Related Art

As solar cells are generally made from brittle materials, solar cells can be fractured easily by external forces during manufacturing processes or transportation. To avoid damaging solar cells, many protection measures—protection tape, for example—have been used. However, a solar cell still can get damaged when an external force is imposed on it locally.

In a typical manufacturing facility, losses of solar cells resulting from cracking can be as high as 5-10%. This problem can get worse when the thickness of solar cells is expected to be as thin as possible to reduce material cost.

To solve the problem, one solution is to use thin film materials to manufacture solar cells, and the related arts can be found in U.S. Pat. No. 6,887,650 (relating to a method of manufacturing thin film devices), U.S. Pat. No. 6,682,990 (relating to a production method of a thin-film single-crystal Si solar cell), U.S. Pat. No. 6,452,091 (relating to a method of producing thin-film single-crystal device and solar cell module), U.S. Pat. No. 5,000,816 (relating to an art of peeling a thin film from a base plate), and U.S. Pat. No. 4,855,012 (relating to a pull-raising member and pull-raising unit for peeling a thin film from a base plate).

However, as the solar cells made from thin film materials tend to have low energy-conversion efficiencies, these proposals are only suitable for certain applications.

Another solution is to make a thin substrate sandwiched between flexible plastic encapsulation layers to provide flexibility, as that disclosed in U.S. Pat. No. 8,450,184 (relating to a thin substrate fabrication using stress-induced spalling). However, as this method requires additional material layers and multiple concomitant adhesion steps, the manufacturing cost will increase accordingly.

Besides, please refer to FIG. 1, which illustrates a distribution of failure stress versus thickness of conventional solar cells. As illustrated in FIG. 1, the failure stress has a peak when the thickness is around 200 μm, and decreases rapidly when the thickness gets smaller. In addition, please refer to FIG. 2, which illustrates a distribution of energy-conversion efficiency versus thickness of conventional solar cells. As illustrated in FIG. 2, the energy-conversion efficiency begins to decrease rapidly after the thickness falls below 50 μm.

From the description above, it can be concluded that if the thickness of a conventional solar cell is reduced to around 50 μm, the failure stress thereof will become relatively small and the conventional solar cell will fracture easily. As a result, it is not easy to get a thin solar cell having both high failure stress and high energy-conversion efficiency.

To solve the foregoing problem, a novel structure for solar cells is needed.

### SUMMARY OF THE INVENTION

One objective of the present invention is to disclose a solar cell, which is capable of preventing a stress concentrating on a local area of the solar cell.

Another objective of the present invention is to disclose a solar cell, which has a thin thickness but possesses high bending strength and high energy-conversion efficiency.

Still another objective of the present invention is to disclose a solar cell, which can bring forth a high yield rate thereof.

To attain the foregoing objectives, a bendable solar cell capable of optimizing thickness and conversion efficiency is proposed, comprising:

a solar cell body having a top surface, a bottom surface, and four side walls; and

a layer of nanostructures located on said side walls, wherein said solar cell body has a thickness ranging from about 50 μm to about 120 μm, and said layer of nanostructures has a depth ranging from about 2 μm to 8 μm.

In one embodiment, the solar cell body employs an amorphous substrate.

In one embodiment, the solar cell body employs a single-crystal substrate.

In one embodiment, the solar cell body employs a polycrystalline substrate.

In one embodiment, the solar cell body employs a substrate of a material selected from a group consisting of glass, silicon, germanium, carbon, aluminum, gallium nitride, gallium arsenide, gallium phosphide, aluminum nitride, sapphire, spinel, aluminum oxide, silicon carbide, zinc oxide, magnesium oxide, lithium aluminum dioxide and lithium gallium dioxide.

In one embodiment, the nanostructures are formed by an electrochemical etching process.

In one embodiment, the nanostructures are formed by a deposition process.

To make it easier for our examiner to understand the objective of the invention, its structure, innovative features, and performance, we use preferred embodiments together with the accompanying drawings for the detailed description of the invention.

### BRIEF DESCRIPTION OF THE DRAWINGS

FIG. 1 illustrates a distribution of failure stress versus thickness of conventional solar cells.

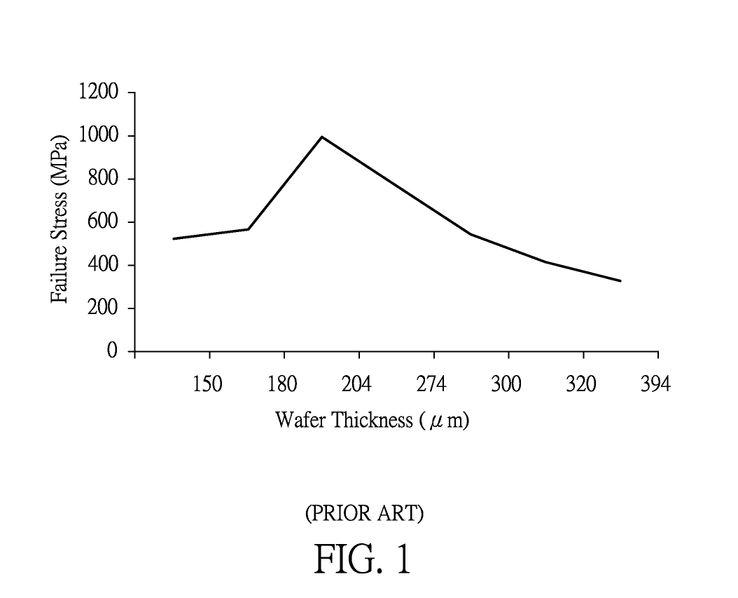

FIG. 2 illustrates a distribution of energy-conversion efficiency versus thickness of conventional solar cells.

FIG. 3 illustrates the structure of an embodiment of a solar cell of the present invention.

FIG. 4 illustrates an energy conversion efficiency comparison chart for solar cells with nanostructures versus solar cells without nanostructures.

FIG. 5 illustrates two I-V curves, in which one is for a solar cell with nanostructures and the other is for a solar cell without nanostructures.

FIG. 6 illustrates a bending strength test result for solar cells with nanostructures at different depths.

FIG. 7 illustrates a design window defined by a wafer thickness ranging from about 50 μm to about 120 μm, and a depth of nanostructures ranging from about 2 μm to about 8 μm.

FIG. 8 illustrates a bending strength test result for solar cells of two different sizes at different nanostructure depths.

### DETAILED DESCRIPTION OF THE PREFERRED EMBODIMENTS

The present invention will be described in more detail hereinafter with reference to the accompanying drawings that show the preferred embodiments of the invention.

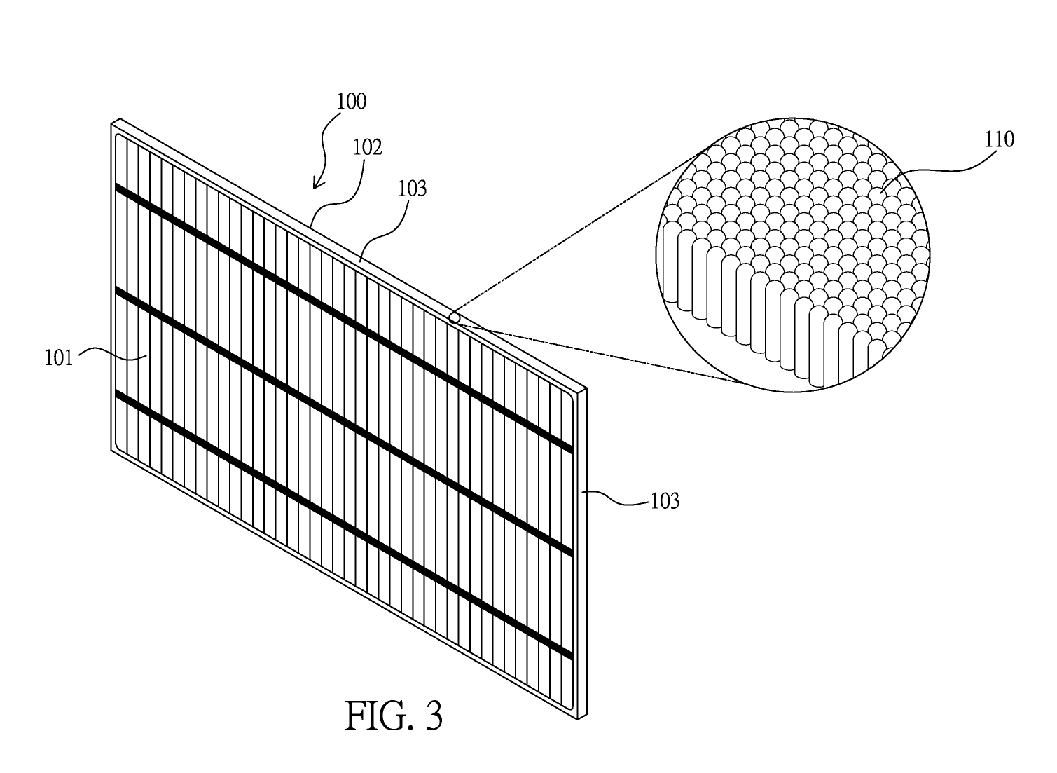

Please refer to FIG. 3, which illustrates the structure of an embodiment of a solar cell of the present invention, in which. As illustrated in FIG. 3, the solar cell includes a solar cell body 100 and a layer of nanostructures 110.

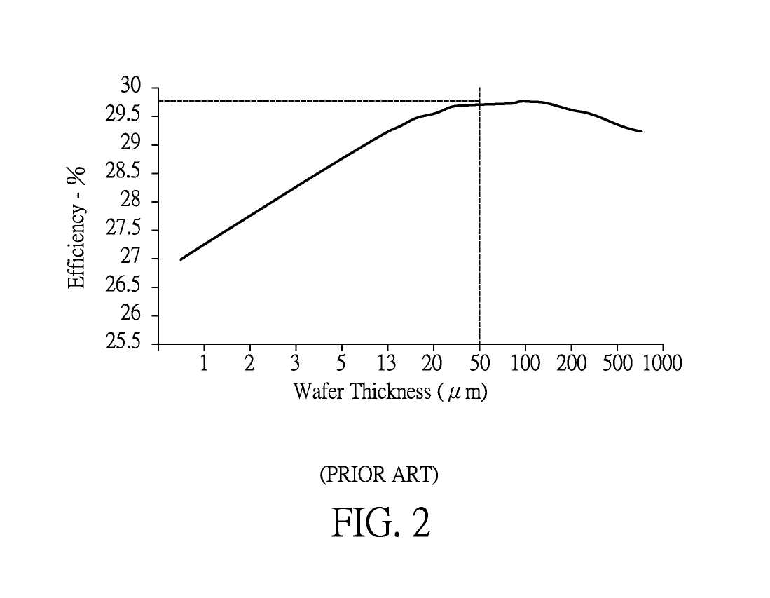

To reduce the material cost, the thickness of the solar cell body 100 is preferably set to be from about 50 μm to about 120 μm. With the thickness set to be within this range, the energy-conversion efficiency of the solar cell can still stay at around a peak value (about 30%, as can be seen in FIG. 2).

As illustrated in FIG. 3, the solar cell body 100 has a top surface 101, a bottom surface 102, and four side walls 103, in which the top surface 101 is used to receive incident light and provide first electrical contacts, and the bottom surface 102 is used to provide second electrical contacts. When light is incident on the top surface 101, electricity can be provided via the first electrical contacts and the second electrical contacts. The solar cell body 100 can employ an amorphous substrate, a single-crystal substrate or a polycrystalline substrate. Besides, the substrate of the solar cell body 100 can be of a material selected from a group consisting of glass (SiO2), silicon (Si), germanium (Ge), carbon (C), aluminum (Al), gallium nitride (GaN), gallium arsenide (GaAs), gallium phosphide (GaP), aluminum nitride (AlN), sapphire, spinel, aluminum oxide (Al2O3), silicon carbide (SiC), zinc oxide (ZnO), magnesium oxide (MgO), lithium aluminum dioxide (LiAlO2), and lithium gallium dioxide (LiGaO2).

Additionally, the solar cell body 100 can have an n-type semiconductor layer stacked on a p-type semiconductor layer to provide a p-n junction for converting photons to electricity.

The layer of nanostructures 110, preferably having a depth ranging from about 2 μm to about 8 μm, are formed on the side walls 103 to increase the failure stress of the solar cell body 100 and therefore make the solar cell body 100 bendable. The principle is that, when a force is applied on the solar cell body 100, the force will be dispersed in all directions to the side walls 103 due to a fact that the layer of nanostructures 110 on the side walls 103 can absorb the force, and the bending strength—the ability to resist a bending stress—of the solar cell body 100 is therefore enhanced significantly.

The layer of nanostructures 110 can be formed by an electrochemical etching process or a deposition process, and before the electrochemical etching process, a nitride removal process (using H₃PO₄ at 160° C. for 30 minutes), a pyramid texture removal process (using HNA for 7 minutes), and a native oxide deposition process (using H2SO4 at 85° C. for 10 minutes) can be used in advance to process the solar cell body 100. The depth of the layer of nanostructures 110 can be adjusted by varying a process time of the electrochemical etching process or the deposition process. Generally, a depth of 2-8 μm of the layer of nanostructures 110 surrounding the solar cell body 100 can result in a much higher bending strength for the solar cell body 100.

Besides, the layer of nanostructures 110 can be formed after or before the solar cells of the solar cell body 100 are complete. That is, the layer of nanostructures 110 can be formed on the side walls 103 after the solar cells are manufactured on a substrate of the solar cell body 100, or formed on the side walls 103 before the solar cells are manufactured on the substrate.

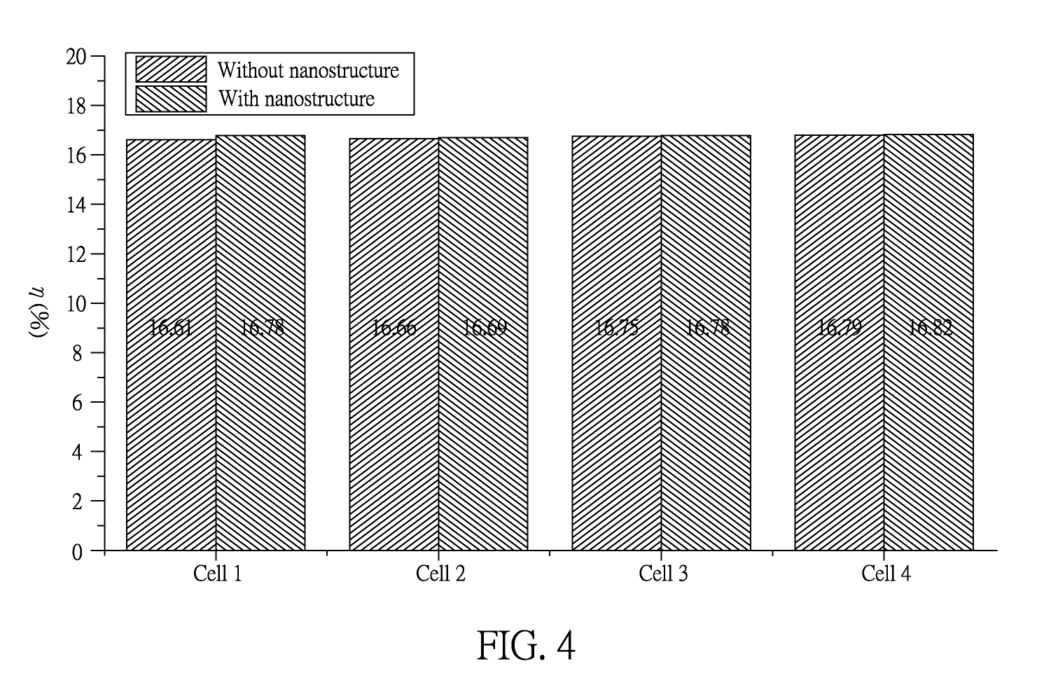

Please refer to FIG. 4, which illustrates an energy conversion efficiency comparison chart for solar cells with nanostructures versus solar cells without nanostructures. As can be seen in FIG. 4, the energy conversion efficiency of the solar cells with nanostructures is almost the same with that of the solar cells without nanostructures. That is, the solar cells with nanostructures provide much higher bending strength without sacrificing the energy-conversion efficiency.

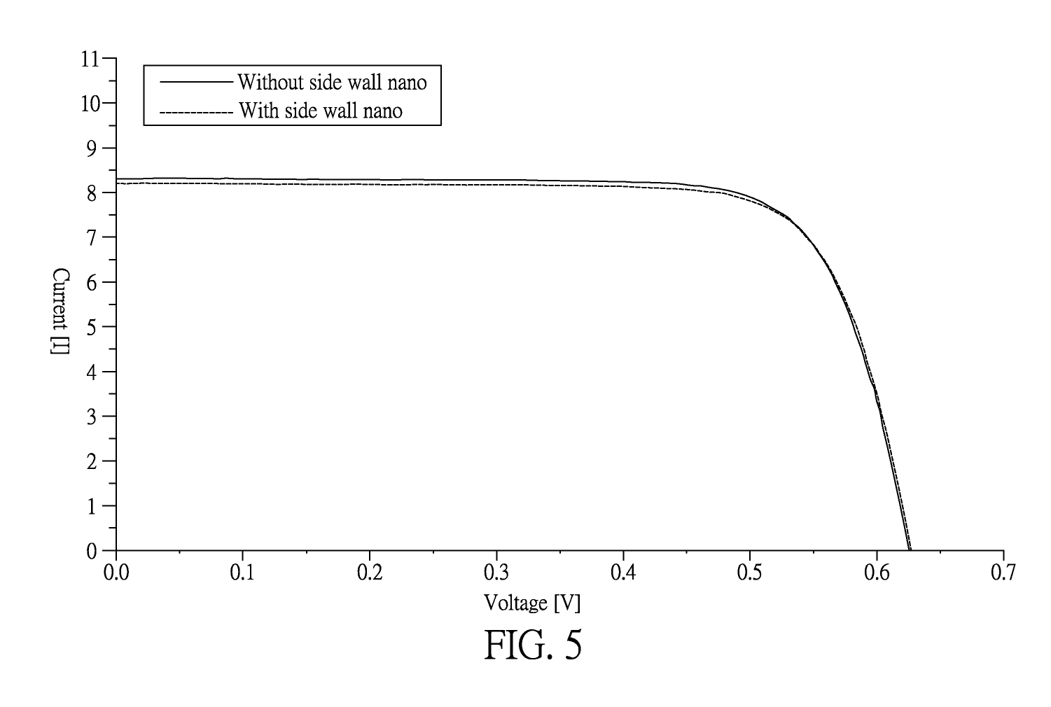

Please refer to FIG. 5, which illustrates two I-V curves, in which one is for a solar cell with nanostructures and the other is for a solar cell without nanostructures. As can be seen in FIG. 5, the I-V curve of the solar cell with nanostructures is almost the same with that of the solar cell without nanostructures. That is, the solar cells with nanostructures provide much higher bending strength without sacrificing the I-V characteristic.

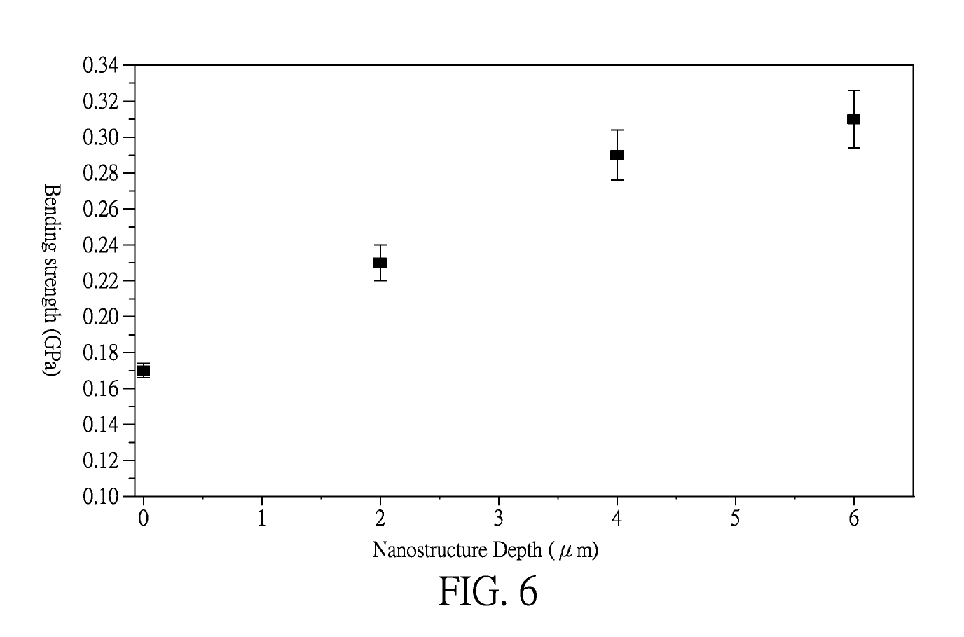

Please refer to FIG. 6, which illustrates a bending strength test result for solar cells with nanostructures at different depths. As can be seen in FIG. 6, the bending strength of a solar cell without nanostructures (that is, at a nanostructure depth of 0 μm) is around 0.17 GPa, while the bending strengths of solar cells with nanostructures at the depth of 2, 4, 6 μm are around 0.23 GPa, 0.29 GPa, and 0.32 GPa, which are much higher than the bending strength of the solar cell without nanostructures. Besides, as the bending strength of the solar cell tends to saturate as the depth of the layer of nanostructures goes beyond 6 μm, the preferable range of the depth is therefore set to be from about 2 μm to about 8 μm. That is, a cost-effective range from about 2 μm to about 8 μm for the depth of the layer of nanostructures promotes the bending strength of the thin solar cell of the present invention, which has a thickness ranging from about 50 μm to about 120 μm, and therefore makes a thin solar cell capable of possessing both high bending strength and high energy-conversion efficiency.

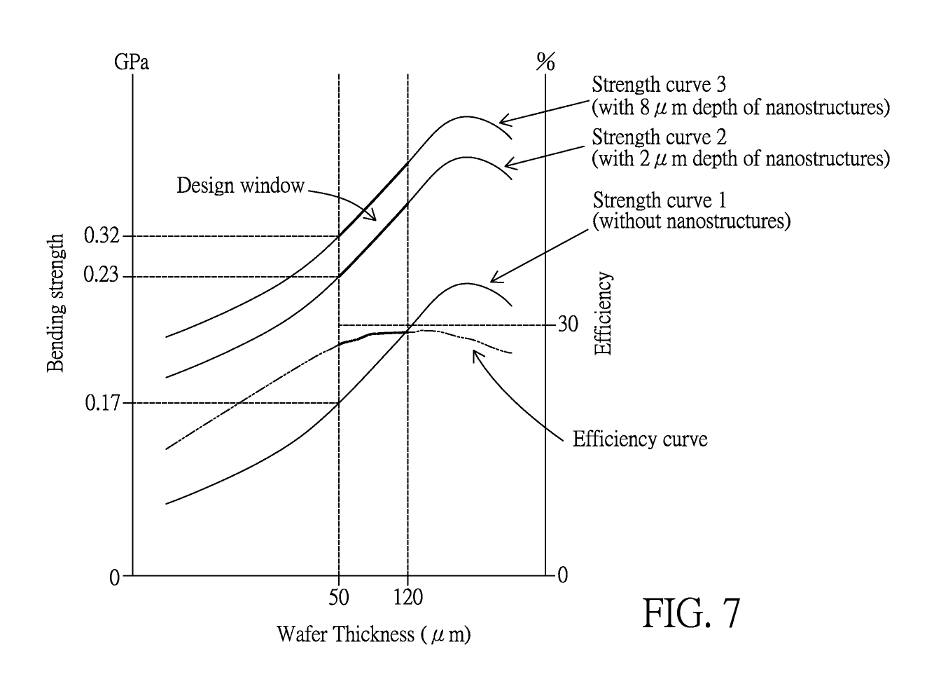

As a result, the present invention has come out a design window for choosing a wafer thickness and a depth of nanostructures on side walls to make a thin solar cell possess both high bending strength and high energy-conversion efficiency. The design window can be perceived more easily with referring to FIG. 7, which illustrates a design window defined by a wafer thickness ranging from about 50 μm to about 120 μm, and a depth of nanostructures ranging from about 2 μm to about 8 μm. As can be seen in FIG. 7, the solar cells manufactured in accordance with this design window exhibit both high bending strength (greater than 0.23 GPa) and high energy-conversion efficiency (about 30%).

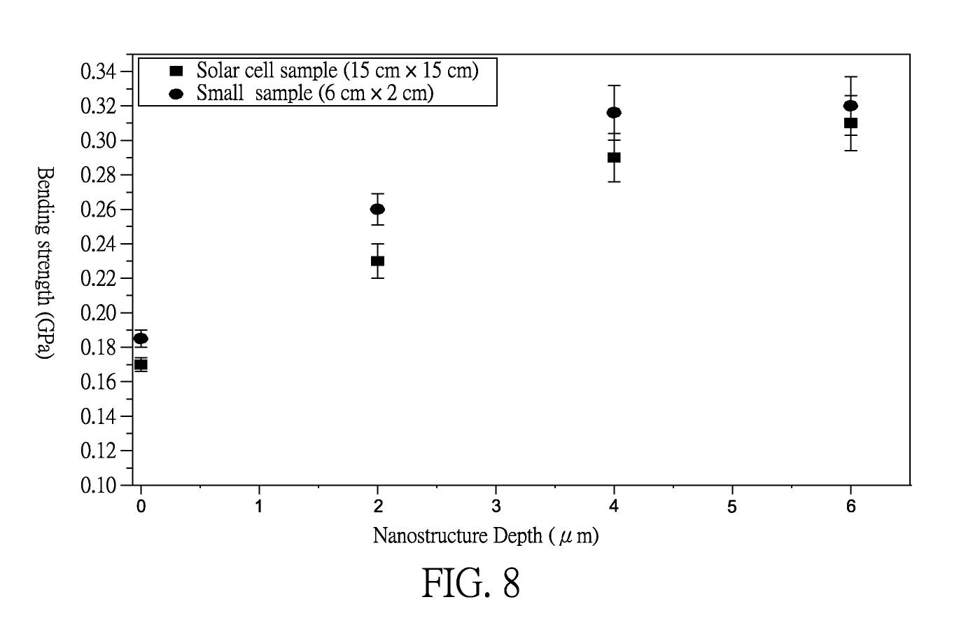

Still, please refer to FIG. 8, which illustrates a bending strength test result for solar cells of two different sizes at different nanostructure depths. As can be seen in FIG. 8, two groups of solar cells, in which one group is of a size of 15 cm by 15 cm and the other group is of a size of 6 cm by 2 cm, show same trend on the bending strength over nanostructure depth. That is, the bending strength of a solar cell without nanostructures (that is, at a nanostructure depth of 0 μm) is around 0.17 GPa, while the bending strengths of solar cells with nanostructures at the depth of 2, 4, 6 μm are around 0.23 GPa, 0.29 GPa, and 0.32 GPa, which are much higher than the bending strength of the solar cell without nano structures.

Due to the designs mentioned above, the present invention offers the following advantages:

1. The solar cell of the present invention can prevent a stress concentrating on a local area thereof.

2. The solar cell of the present invention has a thin thickness but possesses high bending strength and high energy-conversion efficiency.

3. The solar cell of the present invention can bring forth a high yield rate thereof.

While the invention has been described by way of examples and in terms of preferred embodiments, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance over the conventional structure and further complies with the patent application requirements and is submitted to the Patent and Trademark Office for review and granting of the commensurate patent rights.

What is claimed is:

1. A bendable solar cell capable of optimizing thickness and conversion efficiency, comprising:
a solar cell body having a top surface, a bottom surface, and four side walls; and
a layer of nanostructures located on said side walls, wherein said solar cell body has a thickness ranging from about 50 μm to about 120 μm, and said layer of nanostructures has a depth ranging from about 2 μm to 8 μm.

2. The bendable solar cell capable of optimizing thickness and conversion efficiency as claim 1, wherein said solar cell body employs an amorphous substrate.

3. The bendable solar cell capable of optimizing thickness and conversion efficiency as claim 1, wherein said solar cell body employs a single-crystal substrate or a polycrystalline substrate.

4. The bendable solar cell capable of optimizing thickness and conversion efficiency as claim 1, wherein said solar cell body employs a substrate of a material selected from a group consisting of glass, silicon, germanium, carbon, aluminum, gallium nitride, gallium arsenide, gallium phosphide, aluminum nitride, sapphire, spinel, aluminum oxide, silicon carbide, zinc oxide, magnesium oxide, lithium aluminum dioxide and lithium gallium dioxide.

5. The bendable solar cell capable of optimizing thickness and conversion efficiency as claim 1, wherein said layer of nanostructures are formed by an electrochemical etching process.

6. The bendable solar cell capable of optimizing thickness and conversion efficiency as claim 1, wherein said layer of nanostructures are formed by a deposition process.
